(19) United States
(12) Patent Application Publication
(10) Pub. No.: US 2003/0068125 A1
(43) Pub. Date: Apr. 10, 2003

(54) Semiconductor laser device, semiconductor laser module and optical fiber amplifier using the semiconductor laser module

(75) Inventors: Junji Yoshida, Tokyo (JP); Satoshi Irino, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 10/259,476

(22) Filed: Sep. 30, 2002

(30) Foreign Application Priority Data
Sep. 28, 2001 (JP) 2001-304436

(51) Int. Cl. G02B 6/30; G02B 6/42; H01S 5/00

(52) U.S. Cl. 385/27; 385/49; 359/341.1; 359/344; 372/43

(57) ABSTRACT

An n-InP cladding layer, a GRIN-SCH-MQW active layer, a p-InP spacer layer, a p-InP cladding layer and a p-InGaAsP contact layer are sequentially laminated on an n-InP substrate, and an n-type electrode is disposed on a lower portion of the n-InP substrate. Also, a diffraction grating is disposed on a portion region of the p-InP spacer layer, and an insulating film is disposed on the p-InGaAsP contact layer corresponding to the diffraction grating so that injected current is prevented from flowing in respect to the diffraction grating.

### FIELD OF THE INVENTION

The present invention relates to a semiconductor laser device, a semiconductor laser module and an optical fiber amplifier using the device or the module. More particularly, this invention relates to a semiconductor laser device, a semiconductor laser module and an optical fiber amplifier using the device or the module, suitable for an excitation light source of an optical fiber amplifier which is stable and can obtain an optical gain.

### BACKGROUND OF THE INVENTION

In recent years, as various multimedia such as Internet becomes widespread, a demand of high capacity and high speed data transmission in the optical communication system is increasing. Conventionally, in the optical communication, it is common to transmit information by a single wavelength in a band of 1310 nm or 1550 nm of a wavelength having small light absorption in an optical fiber. In this system, it is necessary to increase the number of cores of optical fibers to be disposed in a transmission path so as to transmit a large quantity of information, and there is a problem in that with an increase in the transmission capacity, the cost also increase.

Therefore, a DWDM (Dense-Wavelength Division Multiplexing) communication system is used. In this DWDM communication system, an EDFA is mainly used to transmit information using a plurality of wavelengths in the 1550 nm band which is the operation band thereof. In the DWDM communication system or the WDM communication system, since optical signals of a plurality of different wavelengths are simultaneously transmitted using one optical fiber, it is unnecessary to newly add a line, and it is possible to remarkably increase the transmission capacity of the network.

A common WDM communication system using the EDFA has been put into actual use from 1550 nm band which is easy for flatting the gain, and recently, the band has been expanded to 1580 nm which has not been utilized due to a small gain coefficient. However, since a low loss band of the optical fiber is wider than a band capable of being amplified by the EDFA, the spotlight has centered on an optical amplifier operated in the band outside the EDFA band, i.e., the Raman amplifier.

A gain wavelength range of an optical fiber amplifier using a rare earth ion such as erbium as a medium is determined by an energy level of ion, but the Raman amplifier has a characteristic that the gain wavelength range is determined by a wavelength of an exciting light. Therefore it is possible to amplify any optical wavelength range by selecting the exciting light wavelength.

In the Raman amplification, when a strong exciting light is incident onto optical fiber, a gain appears on the long wavelength side by about 100 nm from the exciting light wavelength by a stimulated Raman scattering, and when a signal light in the wavelength range having this gain is incident onto the optical fiber in this excited state, this signal light is amplified. Therefore, in the WDM communication system using the Raman amplifier, it is possible to further increase the number of channels of the signal light as compared with a communication system using the EDFA.

FIG. 13 is a block diagram that shows a structure of a conventional Raman amplifier used for the WDM communication system. In FIG. 13, semiconductor laser modules 182a to 182d which include Fabry-Perot type semiconductor light emission elements 180a to 180d and fiber gratings 181a to 181d respectively in pair, and output laser beams which are the excitation light source to polarization beam combiners 61a and 61b. The wavelengths of laser beams output from the respective semiconductor laser modules 182a and 182b are the same, but lights having different planes of polarization are multiplexed by the polarization beam combiner 61a. Similarly, the wavelength of laser beams output from the respective laser modules 182c and 182d are the same, but lights which have different planes of polarization is multiplexed by the polarization beam combiner 61b. The polarization beam combiners 61a and 61b output the polarization-multiplexed laser beams respectively to the WDM coupler 62. The wavelengths of laser beams output from the polarization beam combiners 61a and 61b are different from each other.

The WDM coupler 62 couples the laser beam output from the polarization beam combiners 61a and 61b through an isolator 60, and outputs it to an amplification fiber 64 as the exciting light through a WDM coupler 65. The signal light to be amplified is input from a signal light input fiber 69 through an isolator 63 to the amplification fiber 64 to which the exciting light has been input, and it is coupled with the exciting light and is Raman-amplified.

The signal light (amplified signal light) Raman-amplified in the amplification fiber 64 is input to a monitor light distribution coupler 67 through a WDM coupler 65 and an isolator 66. The monitor light distribution coupler 67 outputs a part of the amplified signal light to a control circuit 68, and outputs the remaining amplified signal light to a signal optical output fiber 70 as the output laser beam.

The control circuit 68 controls the light emitting state, e.g., the optical intensity of the respective semiconductor light emission elements 180a to 180d based on the input part of the amplified signal light, and performs feedback control so that the gain band of the Raman amplification has a flat characteristic.

FIG. 14 is a diagram that shows a schematic structure of the semiconductor laser module using the fiber grating. In FIG. 14, a semiconductor laser module has a semiconductor light emission element 202 and an optical fiber 203. The semiconductor light emission element 202 has an active layer 221. The active layer 221 is provided with a light reflection surface 222 at one end, and a light radiation surface 223 at the other end. Light generated in the active layer 221 is reflected by the light reflection surface 222, and is output from the light radiation surface 223.

The optical fiber 203 is disposed on the light radiation surface 223 of the semiconductor light emission element 202, and is optically coupled to the light radiation surface 223. In a core 232 in the optical fiber 203, a fiber grating 233 is formed at a predetermined position from the light radiation surface 223, and the fiber grating 233 selectively reflects light of the characteristic wavelength. That is, the fiber grating 233 functions as an external resonator, forms are sonator between the fiber grating 233 and the light reflection surface 222, and laser beam of a specific wavelength selected by the fiber grating 233 is output as an output laser beam 241.

However, in the above-described semiconductor laser module (182a to 182d), since a distance between the fiber grating 233 and the semiconductor light emission element 202 is long, RIN (Relative Intensity Noise) becomes large due to resonance between the fiber grating 233 and the light reflection surface 222. In the Raman amplification, the process in which the amplification occurs comes early. Therefore when the exciting light intensity is fluctuated, the Raman gain also fluctuates. The fluctuation of the Raman gain is directly output as the fluctuation of the amplified signal intensity, causing a problem in that stable Raman amplification can not be carried out.

The semiconductor laser module needs to optically couple the optical fiber 203 having the fiber grating 233 with the semiconductor light emission element 202. Since the optical coupling is carried out mechanically in the resonator, there are problems in that the oscillation characteristic of the laser may vary due to mechanical vibrations, and there are consumed a great deal of time and labor to perform an optical axis alignment, and stable exciting light can not be provided.

Incidentally, as the Raman amplifier, in addition to a rear-side excitation scheme in which a signal light is excited from the rear side, like the Raman amplifier shown in FIG. 13, there are a front-side excitation scheme in which a signal light is excited from the front side, and a bi-directional excitation scheme in which a signal light is excited bi-directionally. At present, the-rear-side excitation scheme is mainly used as the Raman amplifier. The reason is that the front-side excitation scheme in which the weak signal light proceeds in the same direction together with the strong exciting light has a problem in that the excited optical intensity fluctuates. Therefore, a stable excitation light source that can be applied also to the front-side excitation scheme is required. That is, when a semiconductor laser module using the conventional fiber grating is used, there is a problem in that the applicable excitation scheme is limited.

Also, the Raman amplification in the Raman amplifier is based on a condition that a polarization direction of the signal light and apolarization direction of the exciting light coincide with each other. That is, the Raman amplification has a polarization dependency of the amplified gain, and it is necessary to reduce an influence caused by a deviation between the polarization direction of the signal light and the polarization direction of the exciting light. According to the rear-side excitation scheme, the signal light has no problem since the polarization becomes random during propagation. However, according to the front-side excitation scheme, the polarization dependency is strong, and it is necessary to reduce the polarization dependency by cross polarization multiplexing, the depolarization of the like of the exciting light. That is, it is necessary to reduce the degree of polarization (DOP).

Further, since an amplification rate which can be obtained in the Raman amplification is relatively low, it is desired that an excitation light source for a Raman amplification with a high output is developed.

### SUMMARY OF THE INVENTION

It is an object of the present invention to provide a semiconductor laser device suitable for a light source for a Raman amplifier which can obtain a stable and high gain, and a semiconductor laser module.

In order to achieve the above object, according to one aspect of the present invention, there is provided a semiconductor laser device which comprises: a semiconductor substrate of a first conductive type; a semiconductor buffer layer of the first conductive type laminated on the semiconductor substrate; an active layer laminated on the semiconductor buffer layer; a first electrode laminated on the active layer; and a second electrode disposed on a back surface of the semiconductor substrate, wherein the semiconductor laser device comprises a spacer layer of a second conductive type laminated on the active layer, a diffraction grating which is disposed on one portion region of the spacer layer of the second conductive type, and which selects a laser beam having a plurality of oscillation longitudinal modes and having a specific central wavelength, and a current non-injection region where injected current does not flow into a portion of the diffraction grating.

According to the above aspect, since the current non-injection region is provided where the injected current does not flow into the portion of the diffraction grating, even when the diffraction grating comprising a constant grating, a central wavelength which the diffraction grating selects in the current non-injection region and a central wavelength which the diffraction grating selects in a region in which current is injected are different from each other, thereby achieving the same function as when a plurality of diffraction gratings are provided.

Also, according to another aspect of the present invention, there is provided a semiconductor laser device which comprises: a semiconductor substrate of a first conductive type; a semiconductor buffer layer of the first conductive type laminated on the semiconductor substrate; an active layer laminated on the semiconductor buffer layer; a first electrode laminated on the active layer; and a second electrode disposed on a back surface of the semiconductor substrate, wherein the semiconductor laser device comprises a spacer layer of a second conductive type laminated on the active layer, and a diffraction grating which is disposed on one portion region of the spacer layer of the second conductive type, and which selects a laser beam having a plurality of oscillation longitudinal modes and having a specific central wavelength; the first electrode has a first portion disposed on a region corresponding to one portion of the diffraction grating and a second portion disposed on a region corresponding to a portion where the diffraction grating does not exist; and the first portion and the second portion are spatially separated and electrically isolated from each other.

According to the above aspect, since the first electrode is structured such that the first portion and the second portion are spatially separated and electrically isolated from each other, control on the optical output of an oscillating laser beam and control on selection of the central wavelength performed by causing current to flow in the portion of the diffraction grating can be performed independently.

Also, according to still another aspect of the present invention, there is provided a semiconductor laser module which comprises the semiconductor laser device described above, a temperature adjusting module which controls a temperature of the semiconductor laser module, an optical fiber which guides the laser beam emitted from the semiconductor laser device outside, and an optical coupling lens system which performs optical coupling of the semiconductor laser device and the optical fiber.

According to the above aspect, by using the above semiconductor laser device, a semiconductor laser module which does not require a fiber grating, where it is unnecessary to perform adjustment of an optical axis or the like, which can be assembled easily, and whose oscillation characteristic is not changed by mechanical vibrations or the like can be realized.

Also, according to still another aspect of the present invention, there is provided an optical amplifier which comprises an excitation light source using the semiconductor laser device described above or the semiconductor laser module described above, a coupler which multiplexes a signal light and an exciting light, and an optical fiber for amplification.

According to the above aspect, by including the above semiconductor laser device or the semiconductor lasermodule, an optical fiber amplifier which has a high optical gain and can perform a stable amplification can be realized.

Other objects and features of this invention will become understood from the following description with reference to the accompanying drawings.

### BRIEF DESCRIPTION OF THE DRAWINGS

FIG. 1 is a side sectional view which shows the structure of a semiconductor laser device according to a first embodiment;

FIG. 2 is a sectional view of the semiconductor laser device shown in FIG. 1 taken along the A-A;

FIG. 3 is a diagram which shows the relation between an oscillation wavelength spectrum and an oscillation longitudinal mode regarding one central wavelength in the semiconductor laser device shown in FIG. 1:

FIGS. 4A and 4B are diagrams which show a relation of a laser beam output power between a single oscillation longitudinal mode and a plurality of oscillation longitudinal modes, and which shows a threshold value of a stimulated Brillouin scattering;

FIG. 5 is a diagram which shows a compound oscillation wavelength spectrum comprising a laser beam having two central wavelengths oscillated from the semiconductor laser device according to the first embodiment and a plurality of oscillation longitudinal modes;

FIG. 6 is a side sectional view which shows the structure of a semiconductor laser device according to a second embodiment;

FIG. 7 is a diagram which shows an optical output characteristic of the semiconductor laser device according to the second embodiment;

FIG. 8 is a side sectional view which shows the structure of a semiconductor laser device according to a third embodiment;

FIG. 9 is a side sectional view which shows the structure of a semiconductor laser module according to a fourth embodiment;

FIG. 10 is a block diagram which shows the structure of a Raman amplifier according to a fifth embodiment;

FIG. 11 is a block diagram which shows the structure of a modified embodiment of the Raman amplifier according to the fifth embodiment;

FIG. 12 is a block diagram which shows the schematic structure of a WDM communication system using the Raman amplifier according to the fifth embodiment;

FIG. 13 is a block diagram which shows the schematic structure of a conventional Raman amplifier; and

FIG. 14 is a diagram which shows the structure of a semiconductor laser module used for the conventional Raman amplifier.

### DETAILED DESCRIPTION

Preferable embodiments of as semiconductor laser device, a semiconductor laser module, and an optical fiber amplifier according to the present invention will be explained below with reference to the accompanying drawings.

In the drawings, identical or similar portions are denoted by identical or similar reference numerals. Incidentally, it should be noted that the figures are illustrative, thus the relation between the thickness and the width of each layer, ratio in thickness of respective layers and the like are different from actual ones. Also, even in mutual relations among the drawings, of course, portions where mutual size relations or ratios are different are included.

First Embodiment

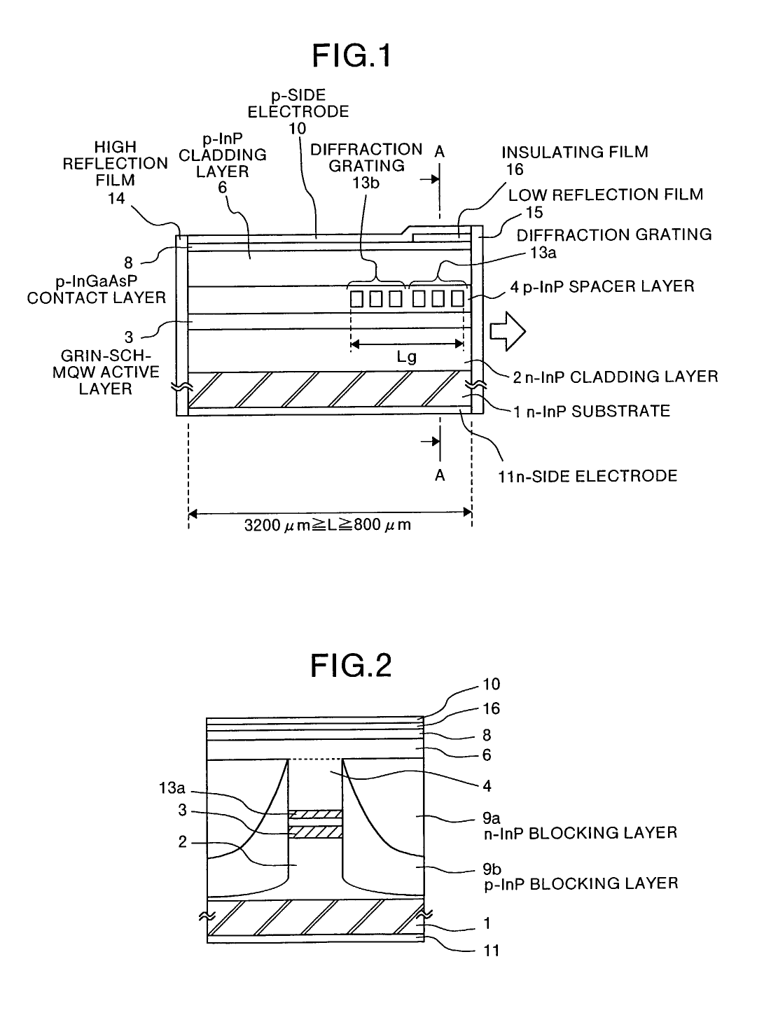

First, a semiconductor laser device according to a first embodiment will be explained. FIG. 1 is a side sectional view of the semiconductor laser device according to the first embodiment, and FIG. 2 is a sectional view of the semiconductor laser device shown in FIG.1 taken along line A-A.

In the semiconductor laser device according to the first embodiment, as shown in FIG. 1, an n-InP cladding layer 2, a GRIN-SCH-MQW (Graded Index-Separate Confinement heterostructure Multi Quantum Well) active layer 3, a p-InP spacer layer 4, a p-InP cladding layer 6, p-InGaAsP contact layer 8, and a p-side electrode 10 are sequentially laminated on a plane (100) of an n-InP substrate 1. Also, an n-side electrode 11 is disposed under the n-InP substrate 1.

The n-InP cladding layer 2 functions as a buffer layer and a cladding layer. By sandwiching the GRIN-SCH-MQW active layer 3 between the n-InP cladding layer 2 and the p-InP cladding layer 6, the semiconductor laser device according to the first embodiment 1 has a double heterostructure, and it has a high radiation efficiency by confining carriers and generated light, effectively.

Also, as shown in FIG. 2, an upper portion of the n-InP cladding layer 2, the GRIN-SCH-MQW active layer 3, the p-InP spacer layer 4 and a lower portion of the p-InP cladding layer 6 are structured so as to be narrower in width than the n-InP substrate 1 along a vertical direction perpendicular to a laser beam radiation direction. A p-InP blocking layer 9b and a n-InP blocking layer 9a are sequentially disposed so as to come into contact with the upper portion of the n-InP cladding layer 2, the GRIN-SCH-MQW active layer 3, the p-InP spacer layer 4 and the lower portion of the p-InP cladding layer 6. These p-InP blocking layer 9b and n-InP blocking layer 9a are for blocking current injected so as not to leak. With such a structure, a structure where the density of current flowing in the GRIN-SCH-MQW active layer 3 is increased and radiation efficiency is improved is obtained.

Also, in the semiconductor laser device according to the first embodiment, a low reflection film 15 is disposed over the entire surface on a radiation side end surface (a right side surface in FIG. 1) and a high reflection film 14 is disposed over the entire surface on a reflection side end surface (the left side surface in FIG. 1).

The high reflection film 14 has a light reflection coefficient of 80% or higher, more preferably 98% or higher. On the other hand, the low reflection film 15 is for preventing the reflection of a laser beam on the radiation side end surface. Accordingly, the low reflection film 15 comprises a film structure with a low reflection coefficient, and it comprises a film structure where the light reflection coefficient is 2% or less, more preferably 1% or less.

Further, diffraction gratings 13a and 13b are disposed within the p-InP spacer layer 4 and in the vicinity of the radiation side end surface. The diffraction gratings 13a and 13b is arranged in series along the laser beam radiation direction. The diffraction gratings 13a and 13b each have a film thickness of 20 nm and a length of Lg=50 μm in the laser beam radiation direction. Also, since such aperiodic structure is employed that the grating period is about 220 nm, a laser beam having a plurality of longitudinal oscillation modes where a central wavelength is 1480 nm is selected.

Each grating constituting the diffraction gratings 13a and 13b is constituted with p-InGaAsP. In this first embodiment, both the diffraction gratings 13a and 13b are formed from arrangement of each grating comprising the same period. Incidentally, a structure is desirable in which an end portion of the diffraction grating 13a on the low reflection film 15 side comes into contact with the low reflection film 15. However, when the distance is within 100 μm, it may be a structure in which the end portion is separated from the low reflection film 15.

An insulating film 16 is disposed on the upper portion of the diffraction grating 13a between the p-InGaAsP contact layer 8 and the p-side electrode 10. The insulating film 16 is for preventing current injected from the p-side electrode 10 from flowing in the vicinity of the low reflection film 15 including the diffraction grating 13a. Incidentally, the insulating film 16 is formed by depositing insulating substances such as AlN, A1₂O₃, MgO, TiO₂ or the like.

Next, the operation of the semiconductor laser device according to this embodiment will be explained. Current injected from the p-side electrode 10 causes radiation recombination of carriers in the GRIN-SCH-MQW active layer 3, and a specific wavelength is selected from the radiated light by the diffraction gratings 13a and 13b to be radiated from the radiation side end surface. Incidentally, the diffraction grating 13a is not subjected to in flow of current by the insulating film 16, but the diffraction grating 13b is subjected to inflow of current. Therefore, the refractive indexes constituting the diffraction gratings 13a and 13b have different values from each other. The features of this embodiment due to this fact will be explained below. First, for easy understanding, a feature obtained by providing a diffraction grating with a single period will be explained below.

On the assumption that the semiconductor laser device according to the first embodiment is used as an excitation light source for a Raman amplifier, its oscillation wavelength λ₀ is 1100 nm to 1550 nm and the resonator length L is 800 μm or more to 3200 μm or less. In general, a mode interval Δλ of the longitudinal mode generated by the resonator of the semiconductor laser device can be expressed in the following equation:

Δλ=λ₀²/(2nL)

wherein an effective refractive index is n. When the oscillation wavelength λ₀ is 1480 μm and the effective refractive index is 3.5, the mode interval Δλ of the longitudinal mode is about 0.39 nm, when the resonator length L is 800 μm, and the mode interval Δλ of the longitudinal mode is about 0.1 nm when the resonator length is 3200 μm. That is, as the resonator length L becomes long, the mode interval Δλ of the longitudinal mode becomes narrow, and the selection condition to oscillate the laser beam of a single longitudinal mode becomes strict.

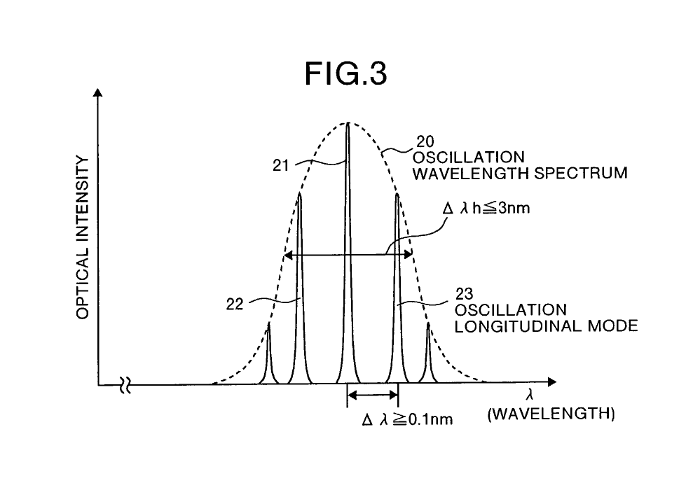

On the other hand, in the first embodiment, the diffraction gratings 13a and 13b select longitudinal modes by Bragg wavelengths thereof. The selection wavelength characteristic by either one of the diffraction gratings 13a and 13b is expressed as an oscillation wavelength spectrum 20 shown in FIG. 3.

As shown in FIG. 3, in the first embodiment, a plurality of oscillation longitudinal modes are made to exist in a wavelength selection characteristic expressed by a half-width Δλh of the oscillation wavelength spectrum 20 by the semiconductor laser device having the diffraction gratings. In the conventional DFB (Distributed Feed back) or the DBR (Distributed Bragg Reflector) semiconductor laser device, when the resonator length L is set to 800 μm or more, a single longitudinal mode oscillation is difficult and thus, a semiconductor laser device having such a resonator length L is not used. In the semiconductor laser device of the first embodiment, however, by positively setting the resonator length L to 800 μm or more, a laser beam is output while including a plurality of oscillation longitudinal modes in the half-width Δλh of the oscillation wavelength spectrum. In FIG. 3, three oscillation longitudinal modes 21 to 23 are included in the half-width Δλh of the oscillation wavelength spectrum 20.

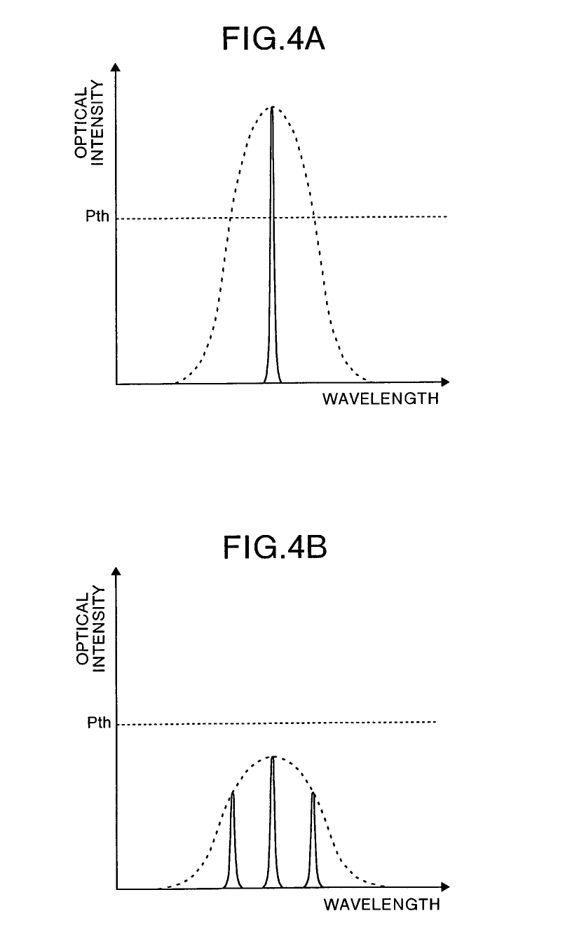

When a laser beam having a plurality of oscillation longitudinal modes is used, it is possible to suppress a peak value of the laser output and to obtain a high laser output value as compared with when a laser beam of single longitudinal mode is used. For example, the semiconductor laser device shown in the first embodiment has a profile shown in FIG. 4B, and can obtain a high laser output with a low peak value. Whereas, FIG. 4A shows a profile of a semiconductor laser device having a single longitudinal mode oscillation when the same laser output is obtained, and has a high peak value.

When the semiconductor laser device is used as an excitation light source for the Raman amplifier, it is preferable to increase an exciting optical output power in order to increase a Raman gain, but when the peak value is high, there is a problem in that stimulated Brillouin scattering occurs and noise increase. Occurrence of the stimulated Brillouin scattering has a threshold value Pₜₕ at which the stimulated Brillouin scattering occurs, and when the same laser output power is obtained, as shown in FIG. 4B, a high exciting optical output power can be obtained within the threshold value Pₜₕ of the stimulated Brillouin scattering, by providing a plurality of oscillation longitudinal modes to suppress the peak value thereof. As a result, a high Raman gain can be obtained.

The wavelength interval (mode interval) Δλ between the oscillation longitudinal modes 21 to 23 is 0.1 nm or more. This is because when the semiconductor laser device is used as an excitation light source for the Raman amplifier, when the mode interval Δλ, is 0.1 nm or less, the probability that the stimulated Brillouin scattering occurs becomes high. As a result, it is preferable that the above-described resonator length L is 3200 mm or less according to the above-described equation of the mode interval Δλ.

From the above viewpoint, it is preferable that the number of oscillation longitudinal modes included in the half-width Δλh of the oscillation wavelength spectrum 20 is plural. In the Raman amplification, since the amplified gain has apolarization dependency, it is necessary to reduce an influence by a deviation between the polarization direction of the signal light and the polarization direction of the exciting light. As method therefor, there exists a method of depolarizing the exciting light. More specifically, there are a method in which the output light from two semiconductor laser devices are polarization-multiplexed by using a polarization beam combiner, and a method in which a polarization maintaining fiber having a predetermined length is used as a depolarizer, to propagate the laser beam emitted from one semiconductor laser device to the polarization maintaining fiber. When the latter method is used as a method for depolarization, as the number of oscillation longitudinal modes increases, coherence of the laser beam becomes lower. Therefore, it is possible to shorten the length of the polarization maintaining fiber required for depolarization. Especially, when the number of oscillation longitudinal mode is four or five, the required length of the polarization maintaining fiber becomes remarkably short. Therefore, when a laser beam emitted from the semiconductor laser device is to be depolarized for use for the Raman amplification, a laser beam emitted from one semiconductor laser device can be depolarized and utilized easily, without polarization synthesizing the emitted light from two semiconductor laser devices for use. As a result, the number of parts used for the Raman amplifier can be reduced, and the Raman amplifier can be made small.

When the oscillation wavelength spectrum width is excessively wide, the coupling loss by the wavelength multiplexing coupler becomes large, and noise and gain fluctuations occur due to the change of the wavelength in the oscillation wavelength spectrum width. Therefore, it is necessary to make the half-width Δλh of the oscillation wavelength spectrum 20 to 3 nm or less, and more preferably, 2 nm or less.

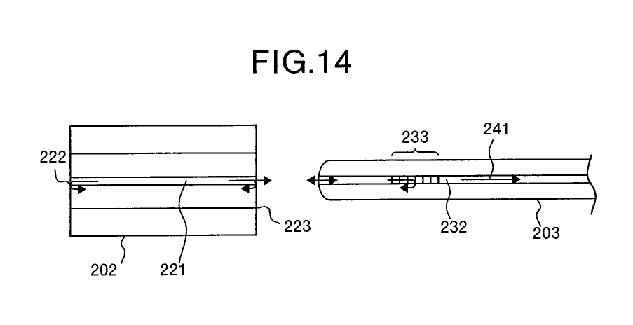

As shown in FIG. 14, since the conventional semiconductor laser device is used as a semiconductor laser module using a fiber grating, a relative intensity noise (RIN) increases due to the resonance between the fiber grating 233 and the light reflection surface 222, and Raman amplification can not be carried out stably. However, according to the semiconductor laser device shown in the first embodiment, since a laser beam emitted from the low reflection film 15 is directly used as an excitation light source for the Raman amplifier, without using the fiber grating 233, the relative intensity noise is reduced and as a result, fluctuations in the Raman gain decrease, and the Raman amplification can be carried out stably.

Also, in the semiconductor laser device according to the first embodiment, there is such a difference that the diffraction grating 13a is not influenced by injection current because of the existence of the insulating film 16 but the diffraction grating 13b is directly influenced by the injection current. Thereby, the influence on the semiconductor laser device according to the first embodiment will be explained below.

In general, regarding a region of p-InGaAsP and p-InP spacer layer 4 constituting the diffraction grating 13b, except for a portion constituting the diffraction grating 13a, its refractive index is changed by applied injection current thereto. For this reason, since the diffraction gratings 13a and 13b are originally equal to each other in physical structure but they are different in refractive index, therefore they are different in optical path length. Therefore, two diffraction gratings whose central wavelengths selected are different exist. For simplification, it is assumed that the diffraction grating 13a has a period Λ₂ and the diffraction grating 13b has a period Λ₂ (≠Λ₁) Incidentally, these grating periods indicate effective values including refractive indexes.

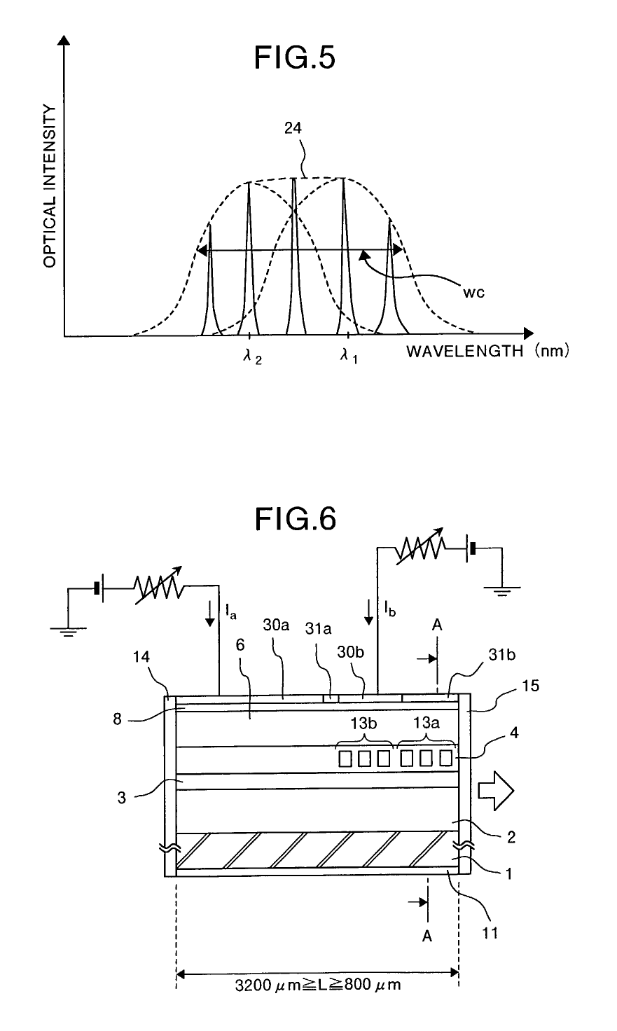

FIG. 5 illustratively shows a spectrum of a laser beam oscillated from the semiconductor laser device according to the first embodiment when the central wavelength λ₁ and the central wavelength λ₂ are selected.

In FIG. 5, the diffraction grating with the period Λ₁ forms an oscillation wavelength spectrum of the wavelength λ₁ and selects three oscillation longitudinal modes within the oscillation wavelength spectrum. On the other hand, the diffraction grating with the period Λ₂ forms an oscillation wavelength spectrum of the wavelength λ₂ and forms three oscillation longitudinal modes within the oscillation wavelength spectrum. In FIG. 5, such a structure can be obtained in which the oscillation longitudinal mode on the side of the short wavelength of the central wavelength λ₁ and the oscillation longitudinal mode on the side of the very long wavelength of the central wavelength λ₂ overlap each other.

Therefore, a compound oscillation wavelength spectrum 24 by the diffraction gratings of the periods Λ₁ and Λ₂ includes four to five oscillation longitudinal modes within the compound oscillation wavelength spectrum 24. As a result, further more oscillation longitudinal modes can be selected and output easily as compared with when a plurality of oscillation longitudinal modes based upon a single central wavelength is formed, so that increase in optical output can be obtained.

In this manner, even though the diffraction gratings 13a and 13b are diffraction gratings having a single period, they have different periods due to existence of the insulating film 16 and they function in a similar manner to when two diffraction gratings selecting different central wavelengths are provided. In a graph shown in FIG. 5, a wavelength difference between λ₁ and λ₂ is about 0.2 nm and the period difference of the diffraction gratings should be set to 0.028 nm in order to realize such a wavelength difference.

However, in the semiconductor laser device according to the first embodiment, it is unnecessary to provide a plurality of diffraction gratings having such a period difference, and a structure in which the insulating film 16 is disposed on an upper portion of one portion of a diffraction grating comprising a single period is enough. By this, manufacturing is made easy and it is possible to provide, a semiconductor laser device with a high yield.

Also, since the refractive index of the p-InP spacer layer 4 around the diffraction grating 13a and the diffraction grating 13b becomes larger in proportion to the intensity of current, the difference between the central wavelength λ₁ selected by the diffraction grating 13a and the central wavelength λ₂ selected by the diffraction grating 13b can be controlled by magnitude of injection current. Therefore, by controlling the injection current, a laser oscillation can be carried out at a desired wavelength so as to compensate the difference from the central wavelength assumed in a design stage.

Also, there is a fear in which a COD (Catastrophic Optical Damage) occurs in the low reflection film 15 disposed on the radiation side end surface of the GRIN-SCH-MQW active layer 3. The COD is a phenomenon in which a feedback cycle of rising of end surface temperature→reduction in band gap of an active layer→light absorption→current concentrations→rising of end surface temperature occurs at in the vicinity of the low reflection film 15 and the end surface melts due to that the cycle becomes a positive feedback so that degradation is caused instantaneously. Now, in the semiconductor laser device according to the first embodiment, since injection current does not flow in the vicinity of the end surface due to existence of the insulating film 16, it is expected that heat generation is suppressed to reduce occurrence probability of the COD.

Second Embodiment

Next, a semiconductor laser device according to a second embodiment will be explained. FIG. 6 is a side sectional view which shows a structure of a semiconductor laser device according to the second embodiment. In the semiconductor laser device according to the second embodiment, like the semiconductor laser device according to the first embodiment, an n-InP cladding layer 2, a GRIN-SCH-MQW active layer 3, a p-InP spacer layer 4, a p-InP cladding layer 6, and a p-InGaAsP contact layer 8 are sequentially-laminatedonaplane (100) of an n-InPsubstrate 1. Also, an n-side electrode 11 is disposed under the n-InP substrate 1. Further, it is similar to the first embodiment in that a low reflection film 15 is disposed on an end surface of a laser beam radiation side (the right side in FIG. 6), a high reflection film 14 is provided on an end surface of the opposed side (the left side in FIG. 6), the light reflection coefficient of the high reflection film 14 is 80% or higher, and the light reflection coefficient of the low reflection film 15 is 2% or less. Further, diffraction gratings 13a and 13b having the same structure about a period and the like are disposed in the vicinity of the low reflection film 15.

Also, a sectional structure perpendicular to the laser radiation direction is similar to the semiconductor laser device according to the first embodiment.

An insulating film 31b is disposed on the p-InGaAs P contact layer 8 in a region corresponding to an upper portion of the diffraction grating 13a. Also, similarly, a p-side electrode 30b is disposed on the p-InGaAsP contact layer 8 in a region corresponding to the diffraction grating 13b, thereby obtaining a structure in which current I_{b} flows in through the p-side electrode 30b. Also, a p-side electrode 30a is disposed on another region of the p-InGaAsP contact layer 8, thereby obtaining a structure in which current Iₐ flows in through the p-side electrode 30a. Here, the p-side electrode 30a and the p-side electrode 30b are insulated from each other by an insulating film 31a. (It is okay that the insulating film 31a is positioned in the contact layer 8, too) Incidentally, the p-side electrodes 30a and 30b are respectively connected to independent current sources, and the current Iₐ, injected from the p-side electrode 30a and the current I_{b} injected from the p-side electrode 30b are different from each other.

In the semiconductor laser device according to this second embodiment, by employing a structure in which an electrode on the p-InGaAsP contact layer 8 is divided into the p-side electrode 30a and the p-side electrode 30b, the following advantages occur.

First, the control on the selection central wavelength of the diffraction grating 13b and the control on the oscillation output of the semiconductor laser device can be carried out independently. In the semiconductor laser device according to the second embodiment, by controlling I_{b}, the refractive indexes of each grating constituting the diffraction grating 13b and the p-InP spacer layer 4 around the diffraction grating 13b can be changed. Therefore, the central wavelength selected by the diffraction grating 13b is controlled. On the other hand, by controlling Iₐ, the oscillation output of the semiconductor laser device can be changed. Since the p-side electrodes 30a and 30b are electrically insulated from each other by the insulating film 31a, the values of Iₐ and Ib can be controlled without depending on each other. Accordingly, the semiconductor laser device according to the second embodiment can perform the control on the selection central wavelength and the control on the oscillation output independently.

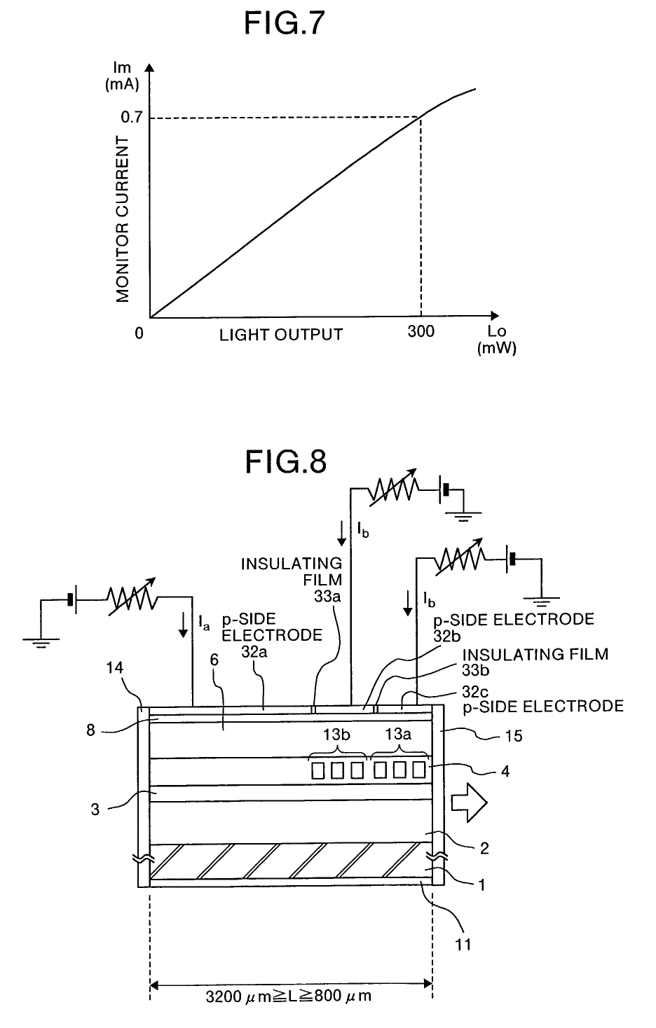

By stabilizing I_{b} which is caused to flow in the diffraction grating 13b, a stable oscillation wavelength can easily be obtained. As a result, in the semiconductor laser device according to the second embodiment, when used as an exciting light source for a Raman amplifier, the output control of the exciting light is made easy. Especially, in a semiconductor laser device with a large output of about 300 mW, when the value of injection current becomes large, a fine fluctuation, caused by longitudinal mode hopping, is prone to occur in an optical output characteristic of a monitor current. However, as shown in FIG. 7, even in the vicinity of an optical output of 300 mW, no fine fluctuation occur in the monitor current so that the output control of the exciting light becomes simple and easy.

Third Embodiment

Next, a third embodiment will be explained with reference to FIG. 8. FIG. 8 is a side sectional view which shows a structure of a semiconductor laser device according to the third embodiment. Regarding a basic structure of the semiconductor laser device according to the third embodiment, explanation about identical or similar portions to portions shown in FIGS. 1 and 6 will be omitted.

In the semiconductor laser device according to the third embodiment, a p-side electrode 32c is disposed on the p-InGaAsP contact layer 8 in a region corresponding to an upper portion of the diffraction grating 13a. Similarly, a p-side electrode 32b is disposed on the p-InGaAsP contact layer 8 in a region corresponding to an upper portion of the diffraction grating 13b, and a p-side electrode 32a is disposed on another region where the p-side electrodes 32b and 32c do not exist. Also, the p-side electrodes 32a and 32b are electrically insulated from each other by an insulating film 33a, and the p-side electrodes 32b and 32c are insulated by an insulating film 33b. Further, the p-side electrodes 32a, 32b and 32c are respectively connected to independent current sources and currents of Iₐ, I_{b} and I_{c} flow in.

Since the three electrodes are disposed on the p-InGaAsP contact layer 8, the semiconductor laser device according to the third embodiment has the following advantages. First, since currents can be applied to the diffraction gratings 13a and 13b independently through the electrodes, the refractive indexes of each grating constituting the diffraction gratings 13a and 13b and a region around the grating can be changed. The optical path lengths of the diffraction gratings 13a and 13b change due to change of the refractive indexes, and an effective period changes. Therefore, the central wavelengths selected by the diffraction gratings 13a and 13b are different from each other as compared with when currents are not injected. Since the value of the central wavelength to be selected changes so as to correspond to the density of injected current, the central wavelengths selected by the diffraction gratings 13a and 13b can be controlled by controlling the magnitudes of currents injected from the p-side electrodes 32c and 32b.

Furthermore, since the currents I_{c}, and I_{b} flowing into the diffraction gratings 13a and 13b can be controlled independently of each other, the central wavelength selected by the diffraction grating 13a and the central wavelength selected by the diffraction grating 13b can be different.

Also, since the currents I_{c}, and I_{b} flowing into the diffraction gratings 13a and 13b and the currents flowing into a portion where a diffraction grating does not exist, are respectively independent of each other, the control on the optical output of the semiconductor laser device according to the third embodiment and the control on the central wavelength to be selected can be performed independently. Thereby, as explained in the second embodiment with reference to FIG. 7, even though large current has been injected, a laser beam which is stable in output can be output.

Furthermore, since the value of the central wavelengths selected by the diffraction gratings 13a and 13b can be controlled, the yield of a semiconductor laser device can be improved. That is, even when a central wavelength assumed in a design stage can be selected, a desired central wavelength can be selected by applying currents through the p-side electrodes 32b and 32a. Accordingly, according to the third embodiment, even a semiconductor laser device which could not conventionally be used as an excitation light source due to that a shift has occurred in the central wavelength, can be used by controlling the central wavelength to be selected.

Incidentally, the semiconductor laser devices according to the first to third embodiments are not limited to the above-described structures. For example, in the semiconductor laser device according to the first embodiment, the n-InP cladding layer 2 has both the functions as the cladding layer and the function as the buffer layer, but a structure in which the n-InP buffer layer is disposed under the n-InP cladding layer 2 can be employed.

Also, regarding the insulating film disposed on the p-InGaAsP contact layer 8, besides such an insulating material such as AIN or the like, for example, the insulating film 16 may be formed of a n-type semiconductor or n-p-n type multilayer structure. In general, this is because, since the p-InGaAsP contact layer 8 is made of a p-type semiconductor, when the insulating film 16 is made of an n-type semiconductor, current hardly flows downwardly in a vertical direction by a pn-junction. In addition, the insulating film may be instituted with an intrinsic semiconductor.

Also, even though the semiconductor laser device does not take a double hetero structure, a wavelength selection by the diffraction grating can be performed. Therefore, it is possible to take a structure of so-called homo-junction laser or a single hetero laser where there is not a difference in bandgap energy between the active layer and the other layers. For the similar reason, even other than the GRIN-SCH-MQW structure, it can be a structure where radiation recombination is possible. Similarly, in the first embodiment, in order to carriers efficiently into the GRIN-SCH-MQW active layer 3, a structure is employed in which the p-InP blocking layer 9b and the n-InP blocking layer 9a are disposed, but the wavelength selection is possible even in a structure where these are omitted.

Further, it is possible to reverse the conductive types in the above embodiment. That is, layers positioned below the GR JN-SCH-MQW active layer 3 maybe made p-type and layers positioned above the GRIN-SCH-MQW active layer 3 may be made n-type. Incidentally, when it is made so, it is necessary to make the conductive type of the diffraction gratings 13a and 13b n-type.

Also, regarding the diffraction gratings 13a and 13b, they have been explained as ones having the structure where the periods or the like are the same in the above embodiments. This has been introduced as simple examples for easy explanation. Of course, the structures of the diffraction gratings 13a and 13b may be different from each other in a state where currents do not flow. Also, even inside the diffraction gratings 13a and 13b, not only a diffraction grating comprising a single period but also a chirped grating structure or a structure where gratings with different periods are mixed may be employed.

Fourth Embodiment

Next, a fourth embodiment of this invention will be explained. In the fourth embodiment, the semiconductor laser device shown in the above-described first to third embodiments are modularized.

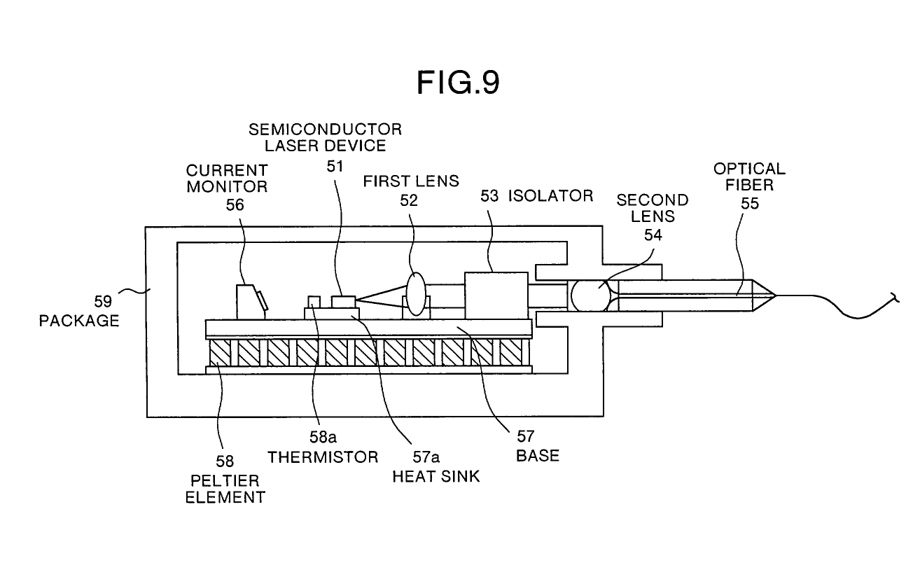

FIG. 9 is a longitudinal sectional view which shows the structure of a semiconductor laser module which is the fourth embodiment of the present invention. The semiconductor laser module according to the fourth embodiment includes a semiconductor laser device 51 corresponding to the semiconductor laser devices shown in the above-described first to third embodiments. Incidentally, this semiconductor laser device 51 is of a junction-down structure in which ap-side electrode is joined to a heat sink 57a. A Peltier element 58 as a temperature control device is disposed on a bottom surface inside a package 59 formed of ceramic or the like as a housing of the semiconductor laser module. A base 57 is disposed on the Peltier element 58, and the heat sink 57a is disposed on the base 57. Current (not shown) is supplied to the Peltier element 58, and cooling and heating operation is performed by the polarity thereof. In order to prevent a deviation in the oscillation wavelength due to a temperature rise of the semiconductor laser device 51, it functions mainly as a cooler. That is, when the laser beam has a wavelength larger than the desired wavelength, the Peltier element 58 cools and controls the temperature to be low, and when the laser beam has a wavelength shorter than the desired wavelength, the Peltier element 58 heats and controls the temperature to be high. To be specific, this temperature control is controlled based on a detection value of a thermistor 58a disposed on the heat sink 57a near the semiconductor laser device 51. The control device (not shown) usually controls the Peltier element 58 such that the temperature of the heat sink 57a is maintained constant. The control device (not shown) also controls the Peltier element 58 such that as the driving current of the semiconductor laser device 51 is increased, the temperature of the heat sink 57a decreases. By performing such a temperature control, it is possible to improve the output stability of the semiconductor laser device 51, and this is also effective for improving the yield. It is preferable to form the heat sink 57a of a material having high thermal conductivity such as diamond. This is because when the heat sink 57a is formed of diamond, heat generation at high current injection is suppressed.

The heat sink 57a on which the semiconductor laser device 51 and the thermistor 58a are arranged, a first lens 52 and a current monitor 56 are disposed on the base 57. A laser beam emitted from the semiconductor laser device 51 is guided onto an optical fiber 55 through the first lens 52, an isolator 53 and a second lens 54. The second lens 54 is provided on a package 59 on an optical axis of the laser beam and is optically coupled with the optical fiber 55 which is externally connected. The current monitor 56 monitors and detects light leaked from the reflection film side of the semiconductor laser device 51.

Here, in the semiconductor laser module, the isolator 53 is interposed between the semiconductor laser device 51 and the optical fiber 55 so that the reflected return light caused by other optical part does not return into the resonator. As this isolator 53, an isolator of a polarization dependent type which can be used incorporated in the semiconductor laser module can be used instead of the in-line fiber type, unlike the conventional semiconductor laser module using the fiber grating. Therefore, an insertion loss caused by the isolator can be reduced, further lower relative intensity noise (RIN) can be achieved, and the number of parts can be reduced.

In the fourth embodiment, the semiconductor laser device shown in the first to third embodiments is modularized. Therefore, the polarization dependent type isolator can be used, and hence the insertion loss can be reduced, the noise and the number of parts can be further reduced.

Fifth Embodiment

Next, a fifth embodiment of the present invention will be explained. In the fifth embodiment, the semiconductor laser module shown in the fourth embodiment is applied to the Raman amplifier.

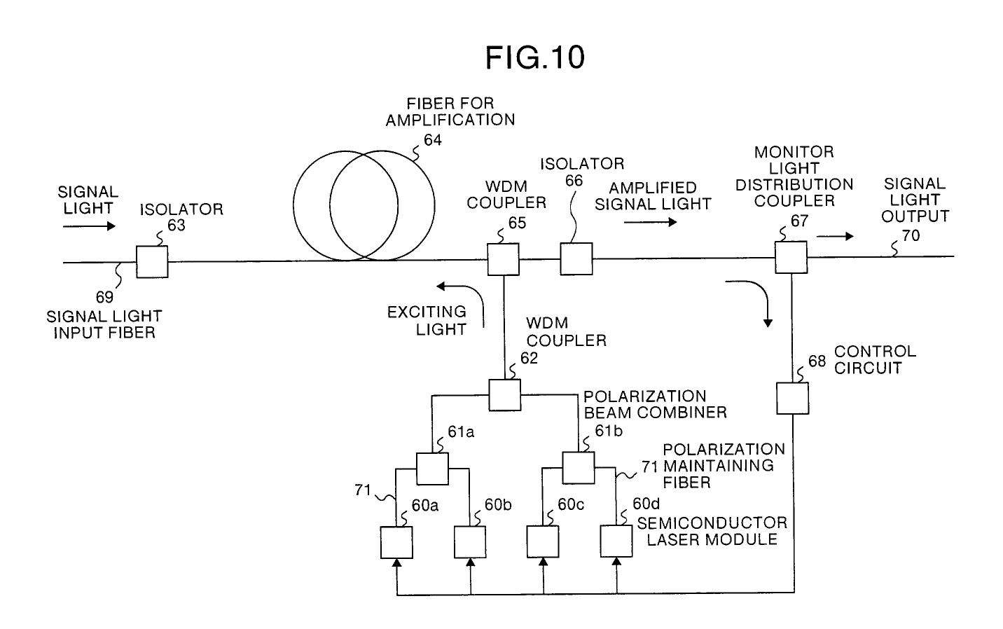

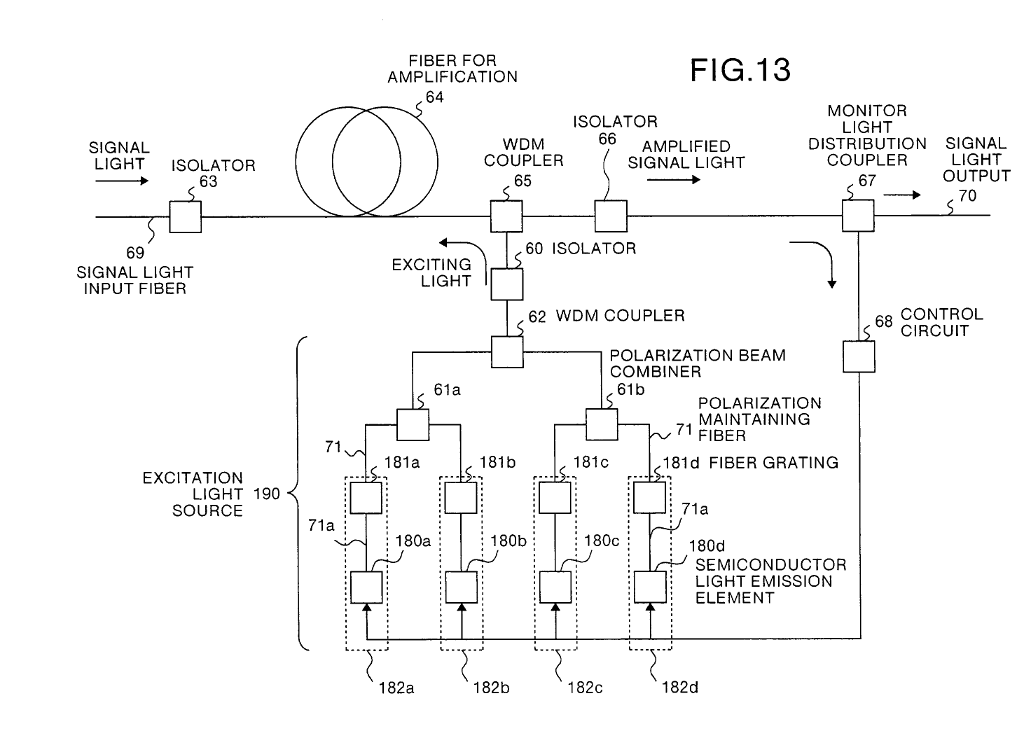

FIG. 10 is a block diagram which shows a structure of a Raman amplifier of the fifth embodiment of the invention. The Raman amplifier is used for the WDM communication system. In FIG. 10, the Raman amplifier uses semiconductor laser modules 60a to 60d having the same structure as that of the semiconductor laser module shown in the fourth embodiment, and it is of a structure such that semiconductor laser modules 182a to 182d shown in FIG. 13 are replaced by the above-mentioned semiconductor laser modules 60a to 60d.

Each of the semiconductor laser modules 60a to 60b outputs a laser beam having a plurality of oscillation longitudinal modes to the polarization beam combiner 61a through a polarization maintaining fiber 71. Each of the semiconductor laser modules 60c and 60d outputs a laser beam having a plurality of oscillation longitudinal modes to the polarization beam combiner 61b through the polarization maintaining fiber 71. The laser beams oscillated by the semiconductor laser modules 60a and 60b have the same wavelengths. The laser beams oscillated by the semiconductor laser modules 60c and 60d have the same wavelengths, but different from the wavelengths of the laser beams oscillated by the semiconductor laser modules 60a and 60b. This is because the Raman amplification has a polarization dependency, and the laser beams are output, after the polarization dependency is eliminated by the polarization beam combiners 61a and 61b.

The laser beams having different wavelengths output from the polarization beam combiners 61a and 61b are multiplexed by a WDM coupler 62, and the multiplexed laser beam is output to an amplification fiber 64 as an exciting light for the Raman amplification through a WDM coupler 65. A signal light to be amplified is input to the amplification fiber 64 to which the exciting light has been input, and is Raman-amplified.

The signal light (amplified signal light) which has been Raman-amplified in the amplification fiber 64 is input to a monitor light distribution coupler 67 through the WDM coupler 65 and an isolator 66. The monitor light distribution coupler 67 outputs a portion of the amplified signal light to a control circuit 68, and outputs the remaining amplified signal light to a signal optical output fiber 70 as output laser beam.

The control circuit 68 controls the laser output state of the semiconductor laser modules 60a to 60d, e.g., the optical intensity, based on a part of the input amplified signal light, and feedback controls so that the gain band of the Raman amplification has a flat characteristic.

In the Raman amplifier shown in the fifth embodiment, a semiconductor laser module 182a in which a semiconductor light-emitting element 180a and a fiber grating 181a are coupled to each other by a polarization maintaining fiber 71a, for example, as shown in FIG. 13, is not used. Instead, there is used the semiconductor laser module 60a in which the semiconductor laser device shown in the first to third embodiments is incorporated. Therefore, it is possible to reduce the use of the polarization maintaining fiber 71a. As a result, reduction in size and weight of the Raman amplifier and cost reduction can be realized.

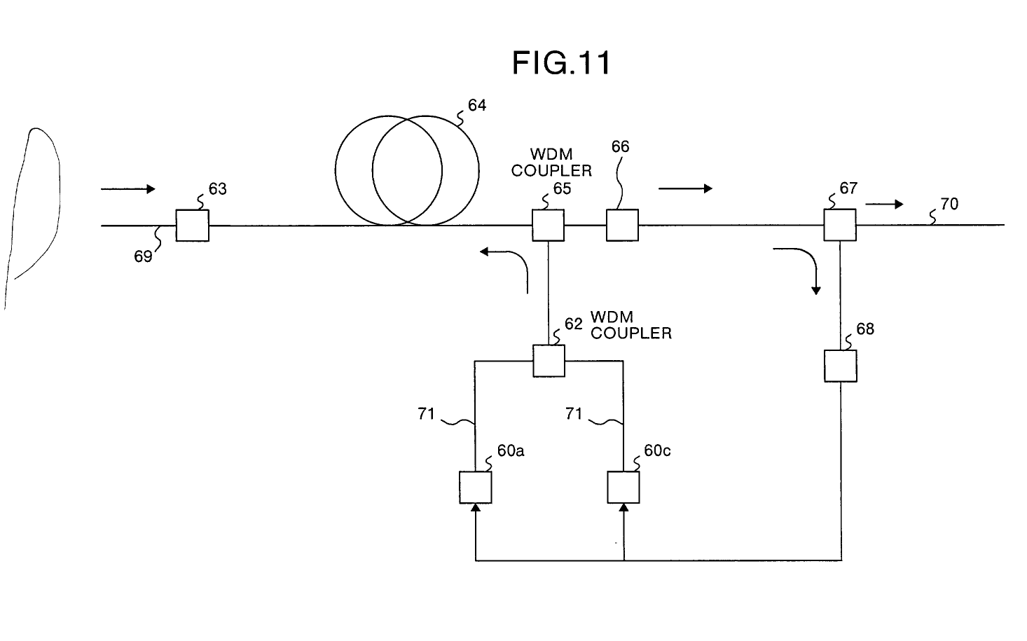

The polarization beam combiners 61a and 61b are used in the Raman amplifier shown in FIG. 10. However, light may also be output directly to the WDM coupler 62 through the polarization maintaining fiber 71 from the semiconductor laser modules 60a and 60c, as shown in FIG. 11. Here, the plane of polarization of semiconductor laser modules 60a and 60c is set to 45 degrees with respect to the polarization maintaining fiber 71. Thereby, the polarization dependency in the optical output which is output from the polarization maintaining fiber 71 can be eliminated, and it is possible to realize a Raman amplifier which is smaller and has a smaller number of parts.

When a semiconductor laser device having a large number of oscillation longitudinal modes is used as a semiconductor laser device incorporated in the semiconductor laser modules 60a and 60d, it is possible to shorten the length of the required polarization maintaining fiber 71. Especially, when the number of the oscillation longitudinal modes is four or five, the length of the required polarization maintaining fiber 71 is greatly shortened and hence, the Raman amplifier can further be simplified and reduced in size. Further, when the number of oscillation longitudinal modes is increased, the coherent length becomes short, the degree of polarization (DOP) is reduced by depolarization, and it is possible to decrease the polarization dependency. As a result, the Raman amplifier can be further simplified and reduced in size.

In this Raman amplifier, alignment of the optical axis is easy as compared with a semiconductor laser module using the fiber grating, and there is no mechanical optical coupling in the resonator. As a result, the stability and reliability of the Raman amplifier can be enhanced.

Further, since the semiconductor laser device of the first to third embodiments includes a plurality of oscillation modes, it is possible to generate high-output exciting light without causing the induced Brillouin scattering and thus, high Raman gain can be stably obtained.

The Raman amplifier shown in FIGS. 10 and 11 is of a rear-side excitation scheme, but since the semiconductor laser modules 60a to 60d output a stable exciting light as described above, stable Raman amplification can be carried out irrespective of the front-side excitation scheme or the bi-directional excitation scheme.

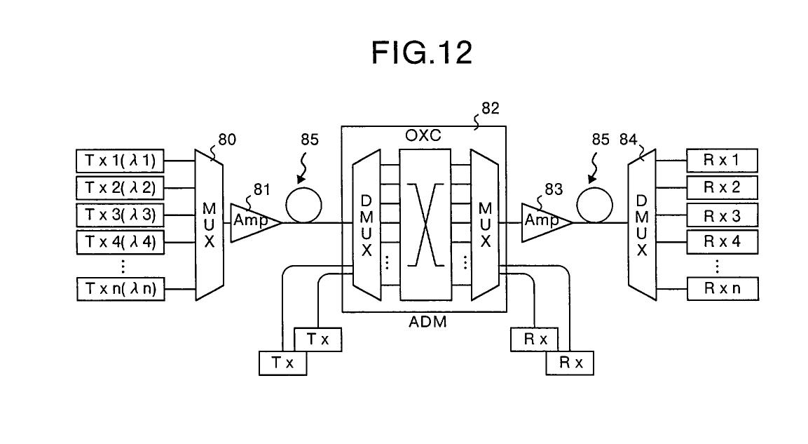

As described above, the above-described Raman amplifier shown in FIG. 10 or 11 can be applied to the WDM communication system. FIG. 12 is a block diagram that shows the schematic structure of the WDM communication system to which the Raman amplifier shown in FIG. 10 or 11 is applied.

In FIG. 12, optical signals having wavelengths λ₁, to λₙ transmitted from a plurality of transmitters Txl to Txn are coupled by an optical coupler 80 and aggregated into one optical fiber 85. On a transmitting path of this optical fiber 85, a plurality of Raman amplifiers 81 and 83 corresponding to the Raman amplifier shown in FIG. 10 or 11 are disposed depending upon the distance so that the attenuated optical signal is amplified. The signal transmitted on the optical fiber 85 is branched by an optical brancher 84 into optical signals having the plurality of wavelength λ₁ to λₙ, and those are received by a plurality of receivers Rx1 to Rxn. An ADM (Add/DropMultiplexer) which adds or drops an optical signal having an optical wavelength may be inserted in the optical fiber 85.

In the above-described fifth embodiment, the semiconductor laser device shown in the first to third embodiments, or the semiconductor laser module shown in the fourth embodiment is used as an excitation light source for the Raman amplification. However, the invention is not limited to this, and it is obvious that they can be also used as the EDFA excitation light source of, for example, 980 nm and 1480 nm.

As explained above, according to the present invention, current non-injection region where injected current does not flow is provided in a portion of the diffraction grating. Therefore, there is the effect that, even in a diffraction grating comprising a constant grating period, a central wavelength selected by the diffraction grating at the current non-injection region and a central wavelength selected by the diffraction grating at a region where current is injected are different from each other so that the same function as when a plurality of diffraction gratings are provided can be achieved.

According to the present invention, the insulating film is disposed. Therefore, there is the effect that injected current can be prevented from flowing into the current non-injection region effectively.

According to the present invention, a structure is employed in which the first electrode is spatially separated into the first portion and the second portion. Therefore, there is the effect that control on the optical output of an oscillating laser beam and control on the central wavelength selection due to flowing current into a portion of the diffraction grating can be performed independently.

According to the present invention, the third portion is further provided in the first electrode. Therefore, there is the effect that the refractive index control of the diffraction grating can be performed more effectively and the yield of the semiconductor laser device can be enhanced.

According to the present invention, since the double hetero-structure is achieved by sandwiching the active layer between the cladding layers from the above and the below, carriers are concentrated in the active layer. Therefore, there is the effect that a semiconductor laser device performing laser oscillation with a high efficiency can be realized.

According to the present invention, the above-described semiconductor laser device is used. Therefore, there is the effect that a semiconductor laser module which does not require a fiber grating or performing of an optical axis alignment, which is assembled easily, and whose oscillation characteristic is not changed due to mechanical vibrations or the like.

According to the present invention, there is the effect that monitoring of the optical output can be performed by providing the light detector and the optical output can be stabilized, and a reflected light from the outside can be prevented by providing the isolator.

According to the present invention, there is the effect that an optical fiber amplifier which has a high amplification rate and can perform stable amplification by including the above-described semiconductor laser device or semiconductor laser module can be realized.

According to the present invention, there is the effect that optical amplification can be more preferably performed by the Raman amplification.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer;
a second electrode disposed on a lower surface of said semiconductor substrate;
a spacer layer of a second conductive type laminated on the active layer;
a diffraction grating disposed on a portion region of the spacer layer of the second conductive type, said diffraction grating being configured to select a laser beam having a plurality of oscillation longitudinal modes having a specific central wavelength; and
a current non-injection region where injected current does not flow into a portion of said diffraction grating.

2. The semiconductor laser device of claim 1, wherein an insulating layer is formed on a portion region of an upper portion of said diffraction gratings.

3. The semiconductor laser device of claim 1, wherein said active layer comprises Graded Index-Separate Confinement heterostructure Multi Quantum Well.

4. A semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer,
said the first electrode having a first portion disposed on a region corresponding to a portion of said diffraction grating and a second portion disposed on a region corresponding to a portion where said diffraction grating does not exist,
said first portion and said second portion being spatially separated from each other;
a second electrode disposed on a lower surface of said semiconductor substrate;
a spacer layer of a second conductive type laminated on the active layer; and
a diffraction grating disposed on a portion region of the spacer layer of the second conductive type, said diffraction grating being configured to select a laser beam having a plurality of oscillation longitudinal modes having a specific central wavelength.

5. The semiconductor laser device of claim 4, wherein the first electrode further has a third portion disposed on a region corresponding to another portion of said diffraction grating, and the third portion is spatially separated from the first portion and the second portion.

6. The semiconductor laser device of claim 4, wherein said active layer comprises Graded Index-Separate Confinement heterostructure Multi Quantum Well.

7. A semiconductor laser module comprising:
a semiconductor laser device comprising:
a semiconductor substrate of a first conductive type;
a semiconductor buffer layer of the first conductive type laminated on said semiconductor substrate;
an active layer laminated on the semiconductor buffer layer; a first electrode laminated on the active layer;
a second electrode disposed on a lower surface of said semiconductor substrate;
a spacer layer of a second conductive type laminated on the active layer;
a diffraction grating disposed on a portion region of the spacer layer of the second conductive type, said diffraction grating being configured to select a laser beam having a plurality of oscillation longitudinal modes having a specific central wavelength; and
a current non-injection region where injected current does not flow into a portion of said diffraction grating;
a temperature adjusting module controlling the temperature of said semiconductor laser device;
an optical fiber guiding the laser beam emitted from said semiconductor laser device to the outside; and
an optical coupling lens system performing an optical coupling between said semiconductor laser device and the optical fiber.

8. The semiconductor laser module according to claim 7, further comprising:
an optical detector which measures a light output of said semiconductor laser device; and
an isolator which suppresses incidence of the returning light reflected from the optical fiber side.

9. A semiconductor laser module comprising:
a semiconductor laser device comprising:
a semiconductor substrate of a first conductive type;
a semiconductor buffer layer of the first conductive type laminated on said semiconductor substrate;
an active layer laminated on the semiconductor buffer layer, a first electrode laminated on the active layer,
said first electrode having a first portion disposed on a region corresponding to a portion of said diffraction grating and a second portion disposed on a region corresponding to a portion where said diffraction grating does not exist,
said first portion and the second portion being spatially separated from each other;
a second electrode disposed on a lower surface of said semiconductor substrate;
a spacer layer of a second conductive type laminated on the active layer; and
a diffraction grating disposed on a portion region of the spacer layer of the second conductive type,
said diffraction grating being configured to select a laser beam having a plurality of oscillation longitudinal modes having a specific central wavelength;
a temperature adjusting module controlling the temperature of said semiconductor laser device;
an optical fiber guiding the laser beam emitted from said semiconductor laser device to the outside; and
an optical coupling lens system performing an optical coupling between said semiconductor laser device and the optical fiber.

10. The semiconductor laser module according to claim 9, further comprising:
an optical detector which measures a light output of said semiconductor laser device; and
an isolator which suppresses incidence of the returning light reflected from the optical fiber side.

11. An optical fiber amplifier comprising:
an excitation light source using a semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer;
a second electrode disposed on a lower surface of said semiconductor substrate;
a spacer layer of a second conductive type laminated on the active layer;
a diffraction grating disposed on a portion region of the spacer layer of the second conductive type, said diffraction grating being configured to select a laser beam having a plurality of oscillation longitudinal modes having a specific central wavelength; and
a current non-injection region where injected current does not flow into a portion of said diffraction grating;
a coupler multiplexing a signal light and an exciting light; and
an optical fiber for amplification.

12. The optical fiber amplifier of claim 11, wherein the optical fiber for amplification amplifies light by a Raman amplification.

13. An optical fiber amplifier comprising:
an excitation light source using a semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer, said the first electrode having a first portion disposed on a region corresponding to a portion of said diffraction grating and a second portion disposed on a region corresponding to a portion where said diffraction grating does not exist, said first portion and said second portion being spatially separated from each other;
a second electrode disposed on a lower surface of said semiconductor substrate;
a spacer layer of a second conductive type laminated on the active layer; and
a diffraction grating disposed on a portion region of the spacer layer of the second conductive type, said diffraction grating being configured to select a laser beam having a plurality of oscillation longitudinal modes having a specific central wavelength; a coupler multiplexing a signal light and an exciting light; and
an optical fiber for amplification.

14. The optical fiber amplifier according to claim 13, wherein the optical fiber for amplification amplifies light by a Raman amplification.

15. An optical fiber amplifier comprising:
an excitation light source using a semiconductor laser module comprising:
a semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer;
a second electrode disposed on a lower surface of said semiconductor substrate;
a spacer layer of a second conductive type laminated on the active layer;
a diffraction grating disposed on a portion region of the spacer layer of the second conductive type, said diffraction grating being configured to select a laser beam having a plurality of oscillation longitudinal modes having a specific central wavelength; and
a current non-injection region where injected current does not flow into a portion of said diffraction grating; a temperature adjusting module controlling the temperature of said semiconductor laser device;
an optical fiber guiding the laser beam emitted from said semiconductor laser device to the outside; and
an optical coupling lens system performing an optical coupling between said semiconductor laser device and the optical fiber;
a coupler multiplexing a signal light and an exciting light; and
an optical fiber for amplification.

16. The optical fiber amplifier according to claim 15, wherein the optical fiber for amplification amplifies light by a Raman amplification.

17. An optical fiber amplifier comprising:
an excitation light source using a semiconductor laser module comprising:
a semiconductor laser device comprising:
a semiconductor substrate of a first conductive type;
a semiconductor buffer layer of the first conductive type laminated on said semiconductor substrate;
an active layer laminated on the semiconductor buffer layer;
a first electrode laminated on the active layer, said the first electrode having a first portion disposed on a region corresponding to a portion of said diffraction grating and a second portion disposed on a region corresponding to a portion where said diffraction grating does not exist, said first portion and said second portion being spatially separated from each other;
a second electrode disposed on a lower surface of said semiconductor substrate;
a spacer layer of a second conductive type laminated on the active layer; and
a diffraction grating disposed on a portion region of the spacer layer of the second conductive type, said diffraction grating being configured to select a laser beam having a plurality of oscillation longitudinal modes having a specific central wavelength; a temperature adjusting module controlling the temperature of said semiconductor laser device;
an optical fiber guiding the laser beam emitted from said semiconductor laser device to the outside; and
an optical coupling lens system performing an optical coupling between said semiconductor laser device and the optical fiber;
a coupler multiplexing a signal light and an exciting light; and
an optical fiber for amplification.

18. The optical fiber amplifier according to claim 17, wherein the optical fiber for amplification amplifies light by a Raman amplification.
